(19) United States
(12) Patent Application Publication
(10) Pub. No.: US 2018/0355502 A1
(43) Pub. Date: Dec. 13, 2018

(54) PROCESS FOR METALIZATION OF COPPER PILLARS IN THE MANUFACTURE OF MICROELECTRONICS

(71) Applicant: MacDermid Enthone Inc., Waterbury, CT (US)

(72) Inventors: Elie Najjar, Norwood, MA (US); John Commander, Old Saybrook, CT (US); Thomas Richardson, Killingworth, CT (US); Tao Chi Liu, Zhubei City (TW); Jiang Chiang, Taipei City (TW)

(21) Appl. No.: 15/617,482

(22) Filed: Jun. 8, 2017

(51) Int. Cl. C25D 7/12; C25D 3/38; C25D 5/02; C25D 5/34; H01L 21/288; H01L 23/00; H01L 21/768; H01L 23/522; H01L 23/532

(52) U.S. Cl. CPC C25D 7/123; C25D 3/38; C25D 5/02; C25D 5/34; H01L 21/2885; H01L 24/11; H01L 23/3114; H01L 23/5226; H01L 23/53228; H01L 24/13; H01L 2224/11462; H01L 2224/13147; H01L 21/76879

(57) ABSTRACT

Features such as bumps, pillars and/or vias can be plated best using current with either a square wave or square wave with open circuit wave form. Using the square wave or square wave with open circuit wave forms of plating current, produces features such as bumps, pillars, and vias with optimum shape and filling characteristics. Specifically, vias are filled uniformly and completely, and pillars are formed without rounded tops, bullet shape, or waist curves. In the process, the metalizing substrate is contacted with an electrolytic copper deposition composition. The deposition composition comprises a source of copper ions, an acid component selected from among an inorganic acid, an organic sulfonic acid, and mixtures thereof, an accelerator, a suppressor, a leveler, and chloride ions.

### BACKGROUND OF THE INVENTION

This invention relates to creating conductive features on integrated circuit wafers such as vias, bumps and pillars using copper electroplating. The invention is particularly suited to plating vias that are relatively deep and/or have a relatively small entry dimension.

Among the applications for the invention is the creation of so-called “through silicon via” interconnections of integrated circuit chips. The demand for semiconductor integrated circuit (IC) devices such as computer chips with high circuit speed and high circuit density requires the downward scaling of feature sizes in ultra-large scale integration (ULSI) and very-large scale integration (VLSI) structures. The trend to smaller device sizes and increased circuit density requires decreasing the dimensions of interconnect features and increasing their density. An interconnect feature is a feature such as a via or trench formed in a dielectric substrate which is then filled with metal, typically copper, to yield an electrically conductive interconnect. Copper, having better conductivity than any metal except silver, is the metal of choice since copper metallization allows for smaller features and uses less energy to pass electricity. In damascene processing, interconnect features of semiconductor IC devices are metallized using electrolytic copper deposition.

A patterned semiconductor integrated circuit device substrate, for example, a device wafer or die, may comprise both small and large interconnect features. Typically, a wafer has layers of integrated circuitry, e.g., processors, programmable devices, memory devices, and the like, built into a silicon substrate. Integrated circuit (IC) devices have been manufactured to contain small diameter vias and sub-micron sized trenches that form electrical connections between layers of interconnect structure. These features have dimensions on the order of about 150 nanometers or less, such as about 90 nanometers, 65 nanometers, or even 45 nanometers.

Through silicon vias are critical components of three-dimensional integrated circuits, and they can be found in RF devices, MEMs, CMOS image sensors, Flash, DRAM, SRAM memories, analog devices, and logic devices.

The depth of a TSV depends on the via type (via first or via last), and the application. Via depth can vary from on the order of about 20 microns to about 500 microns, typically between about 50 microns and about 250 microns or between about 25 and about 200 microns, e.g., between about 50 and about 125 microns. Via openings in TSV have had entry dimensions, such as the diameter, on the order of between about 200 nm to about 200 microns, such as between about 1 and about 75 microns, e.g., between about 2 and about 20 microns. In certain highly dense integrated circuit chip assemblies, the via entry dimension is preferably or necessarily small, e.g., in the range of 2 micron to 20 microns.

Exemplary vias for which the process of the invention is adapted would include 5μ wide×40μ deep, 5μ wide×50μ deep, 6μ wide×60μ deep, and 8μ wide×100μ deep. Thus, it may be seen that the process of the invention is adapted for filling vias having an aspect ratio >3:1, typically greater than 4:1, advantageously in the range between about 3:1 and about 100:1 or between 3:1 and 50:1, more typically in the range between about 4:1 and about 20:1, still more typically in the range between about 5:1 and about 15:1. However, it will be understood that the process is quite effective for filling vias of distinctly lower aspect ratio, e.g., 3:1, 2:1, 1:1, 0.5:1 or even 0.25:1 or lower. Thus, while the novel process offers particular advantages in the case of high aspect ratios, the application of the process to filling lower aspect ratio vias is fully within the contemplation of the invention.

In filling deep via, and especially deep vias with relatively small entry dimensions, it has been found difficult to maintain satisfactory deposition rates throughout the filling process. As the extent of filling exceeds 50%, the deposition rate typically declines, and the rate continues to drop as a function of the extent of filling. The overburden may get thicker as a result. In addition, due to the adsorption of the leveler onto the sidewalls and bottom copper surface as discussed hereinbelow, the impurities content of the deposit may also tend to increase. Deep vias are also vulnerable to formation of seams and voids, a tendency that may also be aggravated where entry dimension is small and aspect ratio is high.

Further, to take advantage of the progressively finer and denser architecture of integrated circuits, it is necessary to provide corresponding ultra-miniaturization of semiconductor packaging. Among the structural requirements for this purpose include increases in the density of input/output transmission leads in an integrated circuit chip.

In flip chip packaging, the leads comprise bumps or pillars on a face of the chip, and more particularly on the side of the chip that faces a substrate, such as a printed circuit board (PCB), to which the circuitry of the chip is connected.

Input and output pads for flip chip circuitry are often provided with solder bumps through which the pads are electrically connected to circuitry external to the chip, such as the circuits of a PCB or another integrated circuit chip. Solder bumps are provided from relatively low melting point base metals and base metal alloys comprising metals such as lead, tin, and bismuth. Alloys of base metals with other electrically conductive metals, such as Sn/Ag alloys are also used. In manufacture of the packaged chip, the bumps are provided as globular molten beads on the so-called under bump metal of the pad, and allowed to solidify in place to form the electrical connector through which current is exchanged between the chip and the external circuit. Unless subjected to lateral or vertical constraint during solidification, solder bumps generally assume a spherical form. As a consequence, the cross-sectional area for current flow at the interface with the under bump metal or pad may depend on the wettability of the under bump structure by the solder bump composition. Absent external constraints on the extent of lateral growth, the height of the bump cannot exceed its lateral dimension, and is diminished relative to the height as wettability of the under bump metal by the molten solder increases. In short, dimensions of an unconstrained solder bump are determined mainly by the surface tension of the molten solder, the interfacial tension between the solder and the under bump metal, and the extent to which the volume of the solder drop can be controlled in operation of the solder delivery mechanism used in the process.

In an array of solder bumps formed on the face of an integrated circuit chip, these factors may limit the fineness of the pitch, i.e., the distances between the centers of immediately neighboring bumps in the array.

In order to achieve a finer pitch, attempts have been made to substitute copper bumps or pillars for the solder by electrodeposition onto the under bump metal. However, it can be difficult to control the electrodeposition process to provide a copper pillar of the desired configuration. While the shape of the main body of the pillar can be determined by forming it within the confines of a cavity having sidewalls formed from a dielectric material, the configuration of the distal end of the pillar may still be unsatisfactory, e.g., excessively domed, excessively dished, or irregular.

By comparison with the provision of solder bumps, manufacturing of copper pillars can suffer a further disadvantage in productivity, and in the effect of productivity on manufacturing cost. While a drop of molten solder can be delivered almost instantaneously once a delivery head is brought into registry with the under bump metal, the rate of electrodeposition of a copper pillar is limited by the maximum current density that can be achieved in the electrodeposition circuit. In commercial practice, the current density is limited by various configuration problems, including the problems of doming, dishing, and irregular configuration at the distal end of a copper pillar, which are aggravated if the current density rises above a limiting value, for example, about 40 A/dm², depending on the application, corresponding to a vertical growth rate of no greater than about 7 μm/min.

Although copper bumps and pillars have substantial advantages over tin/lead solder bumps, a small bead of solder is still used in the manufacturing process to bond the end of the bump or pillar to external circuitry such as the circuit traces of a PCB. However, to assure proper bonding of copper to the solder, and to prevent formation of Kirkendall voids at the copper/solder interface that may result from migration of copper into the solder phase, it has been necessary to provide a nickel cap on the distal end of the bump or pillar as a barrier between the copper phase and the solder phase, thus adding to the expense and complication of the manufacturing process.

Plating chemistry sufficient to copper metallize these features has been developed and finds use in the copper damascene method. Copper damascene metallization relies on superfilling additives, i.e., a combination of additives that are referred to in the art as accelerators, levelers, and suppressors. These additives act in conjunction in a manner that can flawlessly fill copper into the interconnect features (often called “superfilling” or “bottom up” growth). See, for example, Too et al., U.S. Pat. No. 6,776,893, Paneccasio et al., U.S. Pat. No. 7,303,992, and Commander et al., U.S. Pat. No. 7,316,772, the disclosures of which are hereby incorporated as if set forth in their entireties.

### SUMMARY OF THE INVENTION

Briefly, the invention is directed to a process for electroplating features such as vias, bumps and/or pillars in a semiconductor integrated circuit device. The integrated circuit device comprises a surface having features therein. If a via, the via feature comprises a sidewall extending from said surface, and a bottom. The sidewall, bottom and said surface have a metalizing substrate thereon for deposition of copper. The via feature has an entry dimension between 1 micrometers and 25 micrometers, a depth dimension between 50 micrometers and 300 micrometers, and an aspect ratio greater than about 2:1. If a pillar, the process of this invention can create pillars of heights up to 230 micrometers, typically from 190 to 230 micrometers. The metalizing substrate comprises a seed layer and is a cathode for electrolytic deposition of copper thereon. In the process, the metalizing substrate is contacted with an electrolytic copper deposition composition. The deposition composition comprises a source of copper ions, an acid component selected from among an inorganic acid, an organic sulfonic acid, and mixtures thereof, an accelerator, a suppressor, a leveler, and chloride ions. An electrodeposition circuit is established comprising an anode, the electrolytic composition, the aforesaid cathode, and a power source. A potential is applied between the anode and the cathode to create electrodeposition current causing reduction of copper ions at the cathode, thereby plating copper onto the metallizing substrate at the bottom and sidewall of the via, the via preferentially plating on the bottom and lower sidewall to cause filling of the via from the bottom with copper, or otherwise creating the bump or pillar.

The invention is further directed to a process for metalizing a through silicon via feature in a semiconductor integrated circuit device. The device comprises a surface having a via feature therein, the via feature comprising a sidewall extending from said surface, and a bottom. The sidewall, bottom and said surface have a metalizing substrate thereon for deposition of copper. The via feature has an entry dimension between 1 micrometers and 25 micrometers, a depth dimension between 50 micrometers and 300 micrometers, and an aspect ratio greater than about 2:1, preferably between 4:1 and 20:1. If a pillar, the process of this invention can create pillars of heights up to 230 micrometers, typically from 190 to 230 micrometers, measured from top to bottom of the pillar. The metalizing substrate comprises a seed layer and provides a cathode for electrolytic deposition of copper thereon. In the process, the metalizing substrate is contacted with an electrolytic copper deposition composition. The deposition composition comprises a source of copper ions, an acid component selected from among an inorganic acid, an organic sulfonic acid, and mixtures thereof, an accelerator, a suppressor, a leveler, and chloride ions. An electrodeposition circuit is established comprising an anode, the electrolytic composition, the aforesaid cathode, and a power source. A potential is applied between the anode and the cathode during a via filling cycle to generate a cathodic electrodeposition current causing reduction of copper ions at the cathode, thereby plating copper onto the metallizing substrate at the bottom and sidewall of the via, the via preferentially plating on the bottom and lower sidewall to cause filling of the via from the bottom with copper.

The inventors here have found that the features such as bumps, pillars and/or vias can be plated best using current with either a square wave or square wave with open circuit wave form. A square wave consists of applying a forward current density of X amps/sq dm for a predetermined period followed by another current density of Y amps/sq dm for a predetermined period of time, followed by a third current density of X¹ amps/sq dm, followed by a fourth current density of Y¹ amps/sq dm, and then optionally repeating the foregoing cycle, wherein X and X¹ can be the same or different values and Y and Y¹ can be the same or different values but X and Y must be different values of forward current density. A square wave with open circuit wave form is the same as a square wave, except that the current density is reduced to zero at points within the plating cycle for predetermined periods of time. The inventors here have determined that using the square wave or square wave with open circuit wave forms produces features such as bumps, pillars, and vias with optimum shape and filling characteristics. Specifically, vias are filled uniformly and completely, pillars are formed without rounded tops, bullet shape, waist curves.

Other features will be in part apparent and in part pointed out hereinafter.

### BRIEF DESCRIPTION OF THE DRAWINGS

FIG. 1 is a schematic of a pillar with a bullet shape showing a TIR measurement.

FIG. 2 is a photograph of a pillar with a bullet shape and with a waist curve.

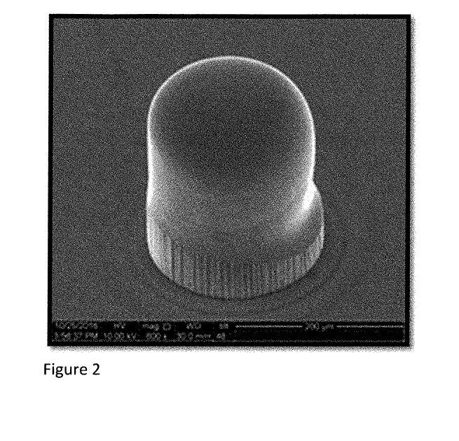

### DESCRIPTION OF PREFERRED EMBODIMENTS

In the electrodeposition of copper onto a metalizing substrate, the accelerator, suppressor, and leveler components of the electrolytic bath co-operate to promote bottom filling of a via or creation of the bump or pillar.

If a via is present, the via feature comprises a sidewall extending from said surface, and a bottom. The sidewall, bottom and said surface have a metalizing substrate thereon for deposition of copper. The via feature has an entry dimension between 1 micrometers and 25 micrometers, a depth dimension between 50 micrometers and 300 micrometers, and an aspect ratio greater than about 2:1. If a pillar, the process of this invention can create pillars of heights up to 230 micrometers, typically from 190 to 230 micrometers, measured from top to bottom of the pillar. The metalizing substrate comprises a seed layer and is a cathode for electrolytic deposition of copper thereon. In the process, the metalizing substrate is contacted with an electrolytic copper deposition composition. The deposition composition comprises a source of copper ions, an acid component selected from among an inorganic acid, an organic sulfonic acid, and mixtures thereof, an accelerator, a suppressor, a leveler, and chloride ions. An electrodeposition circuit is established comprising an anode, the electrolytic composition, the aforesaid cathode, and a power source. A potential is applied between the anode and the cathode to create electrodeposition current causing reduction of copper ions at the cathode, thereby plating copper onto the metallizing substrate at the bottom and sidewall of the via, the via preferentially plating on the bottom and lower sidewall to cause filling of the via from the bottom with copper.

The invention is further directed to a process for metalizing a through silicon via feature in a semiconductor integrated circuit device. The device comprises a surface having a via feature therein, the via feature comprising a sidewall extending from said surface, and a bottom. The sidewall, bottom and said surface have a metalizing substrate thereon for deposition of copper. The via feature has an entry dimension between 1 micrometers and 25 micrometers, a depth dimension between 50 micrometers and 300 micrometers, and an aspect ratio greater than about 2:1. The metalizing substrate comprises a seed layer and provides a cathode for electrolytic deposition of copper thereon. In the process, the metalizing substrate is contacted with an electrolytic copper deposition composition. The deposition composition comprises a source of copper ions, an acid component selected from among an inorganic acid, an organic sulfonic acid, and mixtures thereof, an accelerator, a suppressor, a leveler, and chloride ions. An electrodeposition circuit is established comprising an anode, the electrolytic composition, the aforesaid cathode, and a power source. A potential is applied between the anode and the cathode during a via filling cycle to generate a cathodic electrodeposition current causing reduction of copper ions at the cathode, thereby plating copper onto the metallizing substrate at the bottom and sidewall of the via, the via preferentially plating on the bottom and lower sidewall to cause filling of the via from the bottom with copper.

In various preferred embodiments of the invention, as described herein, a copper bump or pillar having a suitable distal configuration is deposited at a relatively high rate of vertical growth. By “suitable distal configuration” what is meant is that the copper bump or pillar is not unduly domed, unduly dished, or irregular in shape. The rate of growth of bumps and pillars having suitable distal configurations compares favorably with the rate that is achieved using electrodeposition baths that do not involve the composition and process described herein.

The process described herein is useful for building copper bumps and pillars in flip chip packaging and for other wafer-level packaging features such as through silicon vias and redistribution layers (RDLs) and processes directed to the manufacture of integrated circuits. In wafer level packaging, an array of copper bumps or pillars is provided over a semiconductor substrate for interconnection of an electric circuit of a semiconductor device with a circuit external to the device, for example, to a printed circuit board (PCB) or another integrated chip circuit. Current is supplied to the electrolytic solution while the solution is in contact with a cathode comprising an under bump structure on a semiconductor assembly. The semiconductor assembly comprises a base structure bearing the under bump structure, and the latter comprises a seminal conductive layer that may comprise either under bump metal, which is preferably copper or a copper alloy, or an under bump pad that comprises another conductive material such as, for example, a conductive polymer. An under bump metal structure may comprise, for example, a copper seed layer as provided by physical vapor deposition.

In the electrodeposition of pillars, and optionally also in the deposition of bumps, the under bump structure is positioned within or extends into a concavity in the surface of the base structure. The configuration of said bump or pillar is defined by the complementary configuration of the concavity.

In one embodiment, the concavity comprises a floor comprising the under bump pad or under bump metal and a sidewall comprising a dielectric material. In another embodiment, the base structure comprises a dielectric layer comprising a photoresist, mask, or stress buffer material and the concavity comprises an opening in a surface of the dielectric layer. In this instance, the dielectric layer may be removed after electrodeposition of said bump or pillar.

In addition, the sidewall of the concavity can be provided with a dielectric liner prior to electrodeposition of the bump or pillar. In other words, the cavity in which copper is to be deposited may first be provided with a dielectric liner such as silicon dioxide or silicon nitride. The dielectric liner can be formed, for example, by chemical vapor deposition or plasma vapor deposition. Alternatively, organic dielectrics can be used to mitigate a coefficient of thermal expansion mismatch. A photoresist wall of the cavity may have sufficient dielectric properties to obviate the need for a further dielectric layer. However, the nature of the vapor deposition process may cause a further dielectric layer to form on the photoresist wall as well. A seminal conductive layer is then provided by either chemical vapor deposition of a seed layer.

In a process for forming bumps and pillars, the conductive under bump structure may be deposited only at the bottom, i.e., the floor, of the cavity, or in some embodiments, such as those illustrated and described in U.S. Pat. No. 8,546,254 to Lu et al., the subject matter of which is herein incorporated by reference in its entirety, the conductive under bump structure may extend from the bottom of the concavity for some distance upwardly along the sidewall. Preferably, at least the upper sidewall of the concavity remains non-conductive. The bottom of the concavity can be flat, or may comprise a recess filled with polyimide that promotes better bonding. This embodiment of the process differs from filling TSVs, for example, in which the seminal conductive layer is formed over the entire surface of the cavity, including bottom and sidewalls, and metallization is carried out to deposit copper on both bottom and sidewalls.

In carrying out the process described herein, current is supplied to an electrolytic circuit comprising a direct current power source, the aqueous electrodeposition composition, an under bump pad, under bump metal, or array of under bump pads or metal in electrical communication with the negative terminal of the power source and in contact with the electrodeposition composition, and an anode in electrical communication with the positive terminal of the power source and in contact with the electrodeposition composition.

In wafer level packaging, under bump structures are arrayed on a face of a semiconductor wafer, the under bump structure is electrically connected to the negative terminal of the power source, the semiconductor wafer and anode are immersed in the electrodeposition bath, and the power applied. Using the electrodeposition composition described herein within wafer (WIW) uniformity is maintained at a standard deviation not greater than about 10%, for example, while within die (WID) uniformity for dies cut from the wafer is maintained at a standard deviation of, for example, not greater than about 10%. Average feature (WIF) doming is typically about 10%, for example, for baths containing a single leveler. However, greater deviation may be tolerated in situations where productivity gains can be achieved or the device has greater tolerance of the deviation can be remedied downstream by, for example, a mechanical copper removal process. Doming and dishing of bumps and pillars can be minimized, and relatively flat head bumps and pillars can be prepared, using electrodeposition baths containing combinations of levelers as described herein.

The process can be used to provide the under bump metal pads for flip chip manufacturing in which case the metalizing substrate is generally limited to the faces of the bonding pads. Alternatively, with reference to the under bump metal as the floor, the process can be used to form a copper bump or pillar by bottom-up filling of the cavity formed at its floor by the under bump pad or under bump metal and on its sides by the sidewall of an opening in a stress buffer layer and/or photoresist that allows access to the pad or under bump metal. In the latter application, the aperture size of the cavity is roughly comparable to that of a blind through silicon via, and the parameters of the process for building the bump or pillar are similar to those used for filling blind TSVs. However, the concavity wall provided by openings in photoresist or stress-reducing material is ordinarily not seeded and is therefore non-conductive. Only a semiconductor or dielectric under bump structure at the floor of the cavity is provided with a seminal conductive layer, typically comprising a conductive polymer such as a polyimide. In such embodiments, the process is not as dependent on the balance of accelerator and suppressor as it is in the case of bottom filling submicron vias or TSVs.

During the electrodeposition of a bump or pillar within a concavity in the surface of the base structure, lateral growth thereof is constrained by the sidewall(s) of the concavity, and the configuration of the bump or pillar is defined by the complementary configuration of the concavity.

In other embodiments, a bump may be grown over the under bump metal or pad without lateral constraint, or may be caused to grow above the upper rim of a concavity or other lateral constraint, in which case a bump is formed that typically assumes a generally spherical configuration. However, in these embodiments, the configuration of the bump can be influenced by the orientation, configuration and dimension of the anode in the electrolytic circuit.

An anode immersed in an electrodeposition bath can be brought into registry with an under bump structure that is also immersed in the bath, or each of an array of anodes can be brought into registry with a complementary array of under bump structures within the bath, and current applied to deposit a bump or pillar on the under bump structure. If growth of the bump is not constrained by the sidewall of a concavity, or if application of current is continued to a point that the growing bump extends outside the concavity or other lateral constraint, growth of the distal end of the bump assumes a spherical or hemispherical shape. The anode may be pulled away from the substrate along the axis of the growing bump, and the vertical rate of withdrawal of the anode from substrate can affect the shape of distal end of the bump. Generally, the faster the pulling rate, the higher the tangential angle θ (theta) between a horizontal plane and the growing bump at any given distance between the location of the plane and the under bump metal or pad. The pulling rate is not necessarily constant but, if desired, can be varied with deposition time or extent of vertical growth. Alternatively, the under bump structure can be pulled away from the anode instead of the anode being pulled away from substrate. In addition to the pulling rate of the anode, the voltage difference between the anode and the cathode (initially the under bump structure and thereafter the growing bump) can also affect the shape of the bump.

It has been found that, where a solder bump is added at the distal end of a copper bump or pillar that has been formed by the process described herein, the solder bump adheres seamlessly to the copper with a minimum of Kirkendall voids. Thus a solder bump constituted of a low melting alloy such as, for example, Sn/Ag or Sn/Pb, can be directly applied to the copper pillar or bump without need for a cap on the copper consisting of an intermediate layer of nickel or Ni alloy. Also Kirkendall voids are substantially avoided at the juncture between the copper bump or pillar and an under bump metal.

It has further been shown that the use of the compositions described herein provides a high level of within die and within wafer uniformity in the deposition of arrays of copper bumps or pillars on a wafer that has been provided with an array of under bump structures as also described herein.

Using the levelers described herein, high current densities can be established and maintained throughout the electrodeposition process. Thus, the rate at which a bump or pillar may be caused to grow in the vertical direction is at least about 0.25 μm/min, more typically at least about 2.5 or about 3 μm/min, and even more typically at least about 3.3 μm/min. Achievable growth rates range up to about 10 μm/min or higher, equating to a current density of at least about 1 A/dm², at least about 12 A/dm², or at least about 20 A/dm², ranging up to about 30 A/dm² or higher.

Although polymeric and oligomeric reaction products of dipyridyl and a difunctional alkylating agent are highly effective for promoting the deposition of copper bumps and pillars that are free of Kirkendall voids, and for achieving favorable within die (WID), within wafer (WIW) and within feature (WIF) metrics, there is a tendency for pillars produced from the baths described herein to have substantial doming, except in the case of N-benzyl substituted polyethylene imine, wherein the distal end of a bump or pillar is more typically dished.

While the foregoing discusses the invention primarily in the context of embodiments involving bumps and pillars, the compositions and methods have also been proven to be effective in forming other WLP copper features including megabumps, through silicon vias, and redistribution layers. The compositions and processes also apply to heterogeneous WLPs and semiconductor substrates other than Si-based substrates, such as, for example, GaAs-based substrates.

Before immersion in the electrolytic plating bath, the integrated chip or other microelectronic device is preferably “pre-wet” with water or other solution in which the concentration of leveler and suppressor is generally lower than the concentration of these components in the electrolytic bath. Pre-wetting helps to avoid introducing entrained air bubbles when the device is immersed in the electrolytic bath. Pre-wetting may also be used to speed up gap fill. For this purpose, the pre-wet solution may contain a copper electrolyte, with or without additives. Alternatively, the solution can contain only the accelerator component, or a combination of all additives.

Preferably, the device is pre-wet with water, e.g., an aqueous medium devoid of functional concentrations of active components, most preferably deionized water. Thus, as the wetted device is immersed in the electrolytic bath, the water film remains as a diffusion layer (boundary layer) between the bulk electrolytic solution and the metalizing substrate on the field (exterior) of the device and within the via. For the electrolytic process to function, copper ions must diffuse from the bulk solution through the boundary layer to the metalizing substrate. Each other active component, in order to provide its function, must also diffuse through the boundary layer to the cathodic surface. Upon initial immersion, diffusion commences and is driven by the concentration gradient across the boundary layer. After potential is applied, copper ions and other positively charged components are also driven to the cathode by the electrical field. As the electrolytic process proceeds and components of the bulk plating bath are drawn into the boundary layer, the composition of the boundary layer changes, but a relatively quiescent boundary layer is always present as a barrier to mass transfer throughout the electrolytic process.

The accelerator is typically a relatively small organic molecule that functions as an electron transfer agent and which readily diffuses to and attaches itself to the metalizing substrate even in the absence of an applied potential. Copper ions, which are mobile and ordinarily present in the bath at substantially higher concentrations than other components, also diffuse readily through the boundary layer and contact the metalizing substrate. As a cathodic potential is applied to the metalizing substrate, diffusion of copper ions is accelerated under the influence of the electrical field. Initially, the concentrations of suppressor and leveler at the metalizing substrate and within the boundary layer remain relatively low, especially within the via. At surfaces on the exterior of the chip, mass transfer of suppressor and leveler through the boundary layer is promoted by convection and typically further promoted by agitation. But because the via is very small, the extent of convection and the effect of agitation is mitigated, so that transfer of suppressor and leveler to the copper surface within the via is retarded relative to the rate of mass transfer of these components to the metalizing substrate in the field or within the upper reaches of the via. In effect, the entire content of the via might be considered to constitute a boundary layer between the bulk solution outside the via entry and the interior wall (sidewall and bottom) of the via.

The deposition potential is also substantially influenced by the degree of agitation, and more particularly by the extent of turbulence or relative flow at the substrate surface. Higher turbulence at, and/or relative flow along, the substrate has the effect of requiring a more negative electrodeposition potential for deposition of copper. Thus, at the surfaces that are influenced by agitation, agitation suppresses the copper electrodeposition rate by promoting adsorption of leveler and/or a suppressor from an electrolytic bath containing these components. While turbulence and relative flow tend to increase the mass transfer coefficients across the boundary layer for all active components of the electrolytic solution, agitation has a disproportionate effect on the otherwise slow mass transfer of suppressor and leveler relative to the comparatively rapid transfer of copper ions and accelerator, i.e., agitation tends to promote mass transfer of suppressor and leveler to a greater extent than copper ions and accelerator because the copper ions and accelerator are small in size and diffuse relatively rapidly under the influence of the electrical field even in the absence of turbulence. As a consequence, agitation of the electrolytic bath can enhance the selectivity of electrodeposition.

Thus, where the electrolytic bath is agitated, the highest turbulence or relative flow is on the substrate along the surface of the integrated circuit device, with the degree of turbulence decreasing with depth in the via. As a consequence of this gradient of decreasing turbulence, agitation increases the slope of the electrodeposition potential gradient from the top to the bottom of the via, reinforcing the effect of the relative diffusivities of copper ions and accelerator vs. suppressor and leveler in directing the deposition process to begin at the bottom of a via and to progress upwardly in an orderly manner until the via is filled.

Expressed in another way, the accelerated mass transfer of leveler and suppressor to the cathodic surface along face of the field and the upper regions of the via relative to the bottom of the via, as induced by agitation, enhances the differential in conductivity between the electrical path from anode to the bottom of via vs. the electrical paths to the field and the upper regions of the via. In other words, agitation enhances selectivity toward bottom filling. Moreover, under the constant current condition that is preferably maintained during any given phase of the deposition process, enhanced selectivity also contributes to an increase in the absolute current density at the bottom of the via, not merely to an increase relative to the current density in the other regions.

Typical leveler molecules have a molecular weight in the range of about 100 g/mol to about 500,000 g/mol, for example. Because of its size, the leveler diffuses very slowly, significantly more slowly than the suppressor S. Its slow diffusion rate coupled with its strong charge cause the leveler to concentrate at the areas of the metalizing substrate at the surface of the integrated circuit chip and the very top reaches of the via. Where the leveler attaches to the substrate, it is not readily displaced by either the accelerator A or the suppressor S. In essence, the system is driven toward a phase equilbrium between the electrolytic solution and the metalizing surface in which relative concentration of leveler is much higher than accelerator or suppressor at the surface. As a further consequence of its size and charge, the leveler exhibits a strongly suppressive effect on electrodeposition, requiring an even more negative electrodeposition potential than that required by the presence of the suppressor. As long as the leveler is concentrated at the exterior surface (the field) of the chip (or other microelectronic device) and the upper reaches of the via, it is effective to retard electrodeposition on those surfaces, thereby minimizing undesirable overburden and preventing pinching and formation of voids at or near the via entry. Too high a concentration of leveler in the via can substantially retard bottom up capability by redirecting the current path of least resistance and thus increasing the plating rate on the field relative to the bottom of the via and thus compromising the desired bottom-up filling.

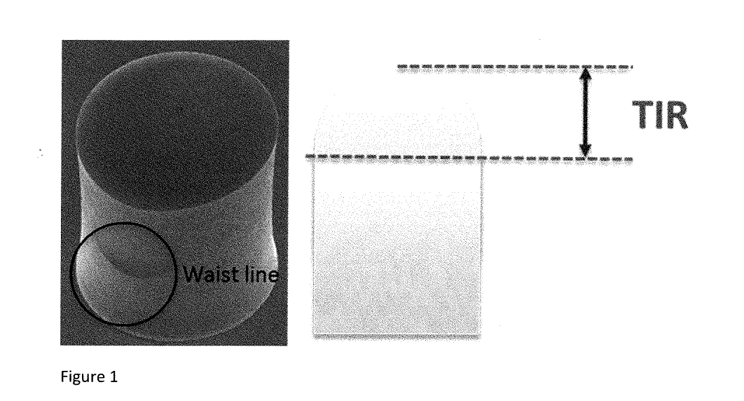

When electrodeposition is initiated, the leveler L does not immediately reach a significant concentration in the boundary layer. Under the influence of convection and agitation, it is fairly readily drawn to the metalizing surface of the field, but does not immediately penetrate the via to any significant extent. However, as the filling cycle progresses, the slow-diffusing leveler eventually works its way into the upper reaches of the via. Since the via is preferentially filling from the bottom, the presence of leveler near the top of the via does not present an obstacle to the bottom-filling process; and at constant current in the electrolytic circuit, adsorption of the leveler to the upper regions of the via redirects current to the bottom of the via thereby actually accelerating the filling rate at the bottom. As the via progressively fills with copper, the leveler continues to diffuse down the via. At locations where the leveler attaches to the via sidewall and bottom up copper surface, a distinctly more negative electrodeposition potential becomes required for copper deposition. As electrodeposition proceeds, the filling level (i.e., the copper filling front) and the location to which the leveler front has diffused progressively approach each other, as shown in FIG. 1C. As the filling level and leveler front come into close proximity, and especially as the leveler adsorbs to a significant extent onto the upper surface of the copper filling the via (see FIG. 1D), the inevitable result is a sharp decrease in the bottom up speed, with current being redirected to the field, with the further adverse effect of increasing copper overburden. As a result, a distinctly higher applied potential is thereafter required to drive the process forward, and under these circumstances the copper deposition pattern resulting from forcing the current is not favorable. At a given applied potential, the bottom up deposition rate significantly declines and copper deposition is redirected to the top surface, extending the deposition cycle and starkly reducing the productivity of the via filling process. Diffusion of leveler into the via retards the bottom up process to the extent that it may take two hours or more to complete filling of the via with copper, and thus increases the overburden.

The inventors here have found that the features such as bumps, pillars and/or vias can be plated best using current with either a square wave or square wave with open circuit wave form. A square wave consists of applying a forward current density of X amps/sq dm for a predetermined period followed by another current density of Y amps/sq dm for a predetermined period of time, followed by a third current density of X¹ amps/sq dm, followed by a fourth current density of Y¹ amps/sq dm, and then optionally repeating the foregoing cycle, wherein X and X¹ can be the same or different values and Y and Y¹ can be the same or different values, but X and Y must be different values of forward current density. A square wave with open circuit wave form is the same as a square wave, except that the current density is reduced to zero at points within the plating cycle for predetermined periods of time. The inventors here have determined that using the square wave or square wave with open circuit wave forms produces features such as bumps, pillars, and vias with optimum shape and filling characteristics. Specifically, vias are filled uniformly and completely, pillars are formed without rounded tops, bullet shape, waste curves.

Generally the current density in the forward current can be progressively stepped up as the deposition process proceeds. At the outset of the plating cycle, the cathode comprises only the seed layer which is of limited conductivity and provides only a limited surface for electrolytic current. Thus, as defined with reference to the entire metalizing surface, the current is relatively low, e.g., in the 0.5 to 1.5 mAkm² range. During this initial lower current density stage, copper deposition is generally conformal—in contrast to “bottom-up”—as the thin and sometimes discontinuous copper seed layer (having been pre-deposited by a non-electrolytic process such as chemical vapor deposition or physical vapor deposition, is converted to a continuous and thicker layer more capable of carrying current associated with bottom-up filling. As copper builds up and covers the metalizing substrate, thus transforming the initial seed layer, the current density can be significantly increased, thereby enhancing the rate of copper deposition and accelerating the completion of the filling cycle when functioning in concert with desorptive anodic intervals in concert with the further compositional and process parameters discussed hereinabove.

The process of the invention is applicable to the manufacture of integrated circuit devices wherein the semiconductor substrate may be, for example, a semiconductor wafer or chip. The semiconductor substrate is typically a silicon wafer or silicon chip, although other semiconductor materials, such as germanium, silicon germanium, silicon carbide, silicon germanium carbide, and gallium arsenide are applicable to the method of the present invention. The semiconductor substrate may be a semiconductor wafer or other bulk substrate that includes a layer of semiconductive material. The substrates include not only silicon wafers (e.g. monocrystalline silicon or polycrystalline silicon), but silicon on insulator (“SOI”) substrates, silicon on sapphire (“SOS”) substrates, silicon on glass (“SOG”) substrates, epitaxial layers of silicon on a base semiconductor foundation, and other semiconductor materials, such as silicon-germanium, germanium, ruby, quartz, sapphire, gallium arsenide, diamond, silicon carbide, or indium phosphide.

The semiconductor substrate may have deposited thereon a dielectric (insulative) film, such as, for example, silicon oxide (SiO₂), silicon nitride (SiNₓ), silicon oxynitride (SiOₓN_{y}), carbon-doped silicon oxides, or low-K dielectrics. Low-K dielectric refers to a material having a smaller dielectric constant than silicon dioxide (dielectric constant=3.9), such as about 3.5, about 3, about 2.5, about 2.2, or even about 2.0. LOW-κ dielectric materials are desirable since such materials exhibit reduced parasitic capacitance compared to the same thickness of SiO₂ dielectric, enabling increased feature density, faster switching speeds, and lower heat dissipation. Low-κ dielectric materials can be categorized by type (silicates, fluorosilicates and organo-silicates, organic polymeric etc.) and by deposition technique (CVD; spin-on). Dielectric constant reduction may be achieved by reducing polarizability, by reducing density, or by introducing porosity. The dielectric layer may be a silicon oxide layer, such as a layer of phosphorus silicate glass (“PSG”), borosilicate glass (“BSG”), borophosphosilicate glass (“BPSG”), fluorosilicate glass (“FSG”), or spin-on dielectric (“SOD”). The dielectric layer may be formed from silicon dioxide, silicon nitride, silicon oxynitride, BPSG, PSG, BSG, FSG, a polyimide, benzocyclobutene, mixtures thereof, or another nonconductive material as known in the art. In one embodiment, the dielectric layer is a sandwich structure of SiO₂ and SiN, as known in the art. The dielectric layer may have a thickness ranging from approximately 0.5 micrometers to 10 micrometers. The dielectric layer may be formed on the semiconductor substrate by conventional techniques.

The electrolytic solution used in the process of the invention is preferably acidic, i.e., having a pH less than 7. Generally, the solution comprises a source of copper ions, a counteranion for the copper ions, an acid, an accelerator, a suppressor, and a leveler. Preferably, the source of copper ions is copper sulfate or a copper salt of an alkylsulfonic acid such as, e.g., methane sulfonic acid. The counteranion of the copper ions is typically also the conjugate base of the acid, i.e., the electrolytic solution may conveniently comprise copper sulfate and sulfuric acid, copper mesylate and methane sulfonic acid, etc. The concentration of the copper source is generally sufficient to provide copper ion in a concentration from about 1 g/L copper ions to about 80 g/L copper ions, more typically about 4 g/L to about 110 g/L copper ions. The source of sulfuric acid is typically concentration sulfuric acid, but a dilute solution may be used. In general, the source of sulfuric acid is sufficient to provide from about 2 g/L sulfuric acid to about 225 g/L sulfuric acid in the copper plating solution. In this regard, suitable copper sulfate plating chemistries include high acid/low copper systems, low acid/high copper systems, and mid acid/high copper systems. In high acid/low copper systems, the copper ion concentration can be on the order of 4 g/L to on the order of 30 g/L; and the acid concentration may be sulfuric acid in an amount of greater than about 100 g/L up to about 225 g/L. In one high acid/low copper system, the copper ion concentration is about 17 g/L where the H₂SO₄ concentration is about 180 g/L. In some low acid/high copper systems, the copper ion concentration can be between about 35 g/L and about 85 g/L, such as between about 25 g/L and about 70 g/L. In some low acid/high copper systems, the copper ion concentration can be between about 46 g/L and about 60 g/L, such as between about 48 g/L and about 52 g/L. (35 g/L copper ion corresponds to about 140 g/L CuSO₄.5H₂O copper sulfate pentahydrate.) The acid concentration in these systems is preferably less than about 100 g/L. In some low acid/high copper systems, the acid concentration can be between about 5 g/L and about 30 g/L, such as between about 10 g/L and about 15 g/L. In some low acid/high copper, the acid concentration can be between about 50 g/L and about 100 g/L, such as between about 75 g/L to about 85 g/L. In an exemplary low acid/high copper system, the copper ion concentration is about 40 g/L and the H₂SO₄ concentration is about 10 g/L. In another exemplary low acid/high copper system, the copper ion concentration is about 50 g/L and the H₂SO₄ concentration is about 80 g/L. In mid acid/high copper systems, the copper ion concentration can be on the order of 30 g/L to on the order of 60 g/L; and the acid concentration may be sulfuric acid in an amount of greater than about 50 g/L up to about 100 g/L. In one mid acid/high copper system, the copper ion concentration is about 50 g/L where the H₂SO₄ concentration is about 80 g/L.

Another advantage of employing copper sulfate/sulfuric is the deposited copper contained very low impurity concentrations. In this regard, the copper metallization may contain elemental impurities, such as carbon, sulfur, oxygen, nitrogen, and chloride in ppm concentrations or less. For example, copper metallization has been achieved having carbon impurity at concentrations of less than about 50 ppm, less than 30 ppm, less than 20 ppm, or even less than 15 ppm. Copper metallization has been achieved having oxygen impurity at concentrations of less than about 50 ppm, less than 30 ppm, less than 20 ppm, less than 15 ppm, or even less than 10 ppm. Copper metallization has been achieved having nitrogen impurity at concentrations of less than about 10 ppm, less than 5 ppm, less than 2 ppm, less than 1 ppm, or even less than 0.5 ppm. Copper metallization has been achieved having chloride impurity at concentrations of less than about 10 ppm, less than 5 ppm, less than 2 ppm, less than 1 ppm, less than 0.5 ppm, or even less than 0.1 ppm. Copper metallization has been achieved having sulfur impurity at concentrations of less than about 10 ppm, less than 5 ppm, less than 2 ppm, less than 1 ppm, or even less than 0.5 ppm.

The alternative use of copper methanesulfonate as the copper source allows for greater concentrations of copper ions in the electrolytic copper deposition composition in comparison to other copper ion sources. Accordingly, the source of copper ion may be added to achieve copper ion concentrations greater than about 50 g/L, greater than about 90 g/L, or even greater than about 100 g/L, such as, for example about 110 g/L. Preferably, the copper methane sulfonate is added to achieve a copper ion concentration between about 70 g/L and about 100 g/L.

When copper methane sulfonate is used, it is preferred to use methane sulfonic acid and its derivative and other organic sulfonic acids as the electrolyte. When methane sulfonic acid is added, its concentration may be between about 1 g/L and about 50 g/L, such as between about 5 g/L and about 25 g/L, such as about 20 g/L.

High copper concentrations in the bulk solution contribute to a steep copper concentration gradient that enhances diffusion of copper into the features. Experimental evidence to date indicates that the copper concentration is optimally determined in view of the aspect ratio of the feature to be copper metallized. For example, in embodiments wherein the feature has a relatively low aspect ratio, such as about 3:1, about 2.5:1, or about 2:1 (depth:opening diameter), or less, the concentration of the copper ion is added and maintained at the higher end of the preferred concentration range, such as between about 90 g/L and about 110 g/L, such as about 110 g/L. In embodiments wherein the feature has a relatively high aspect ratio, such as about 4:1, about 5:1, or about 6:1 (depth:opening diameter), or more, the concentration of the copper ion may be added and maintained at the lower end of the preferred concentration range, such as between about 50 g/L and about 90 g/L, such as between about 50 g/L and 70 g/L. Without being bound to a particular theory, it is thought that higher concentrations of copper ion for use in metallizing high aspect ratio features may increase the possibility of necking (which may cause voids). Accordingly, in embodiments wherein the feature has a relatively high aspect ratio, the concentration of the copper ion is optimally decreased. Similarly, the copper concentration may be increased in embodiments wherein the feature a relatively low aspect ratio.

Chloride ion may also be used in the bath at a level up to about 200 mg/L (about 200 ppm), preferably about 10 mg/L to about 90 mg/L (10 to 90 ppm), such as about 50 gm/L (about 50 ppm). Chloride ion is added in these concentration ranges to enhance the function of other bath additives. In particular, it has been discovered that the addition of chloride ion enhances void-free filling.

The accelerator component of the electrolytic bath preferably comprises an water-soluble organic divalent sulfur compound. A preferred class of accelerators has the following general structure (1):

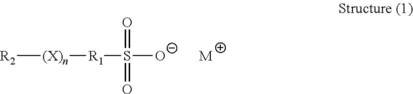

wherein

X is O, S, or S═O;

n is 1 to 6;

M is hydrogen, alkali metal, or ammonium as needed to satisfy the valence;

R₁ is an alkylene or cyclic alkylene group of 1 to 8 carbon atoms, an aromatic hydrocarbon or an aliphatic aromatic hydrocarbon of 6 to 12 carbon atoms; and

R₂ is hydrogen, hydroxyalkyl having from 1 to 8 carbon atoms, or MO₃SR₁ wherein M and R₁ are as defined above.

In certain preferred embodiments, X is sulfur, and n is 2, such that the organic sulfur compound is an organic disulfide compound. Preferred organic sulfur compounds of Structure (1) have the following structure (2):

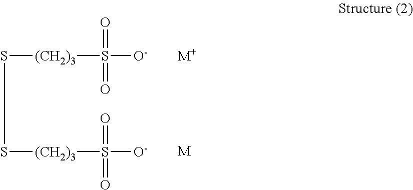

wherein M is a counter ion possessing charge sufficient to balance the negative charges on the oxygen atoms. M may be, for example, protons, alkali metal ions such as sodium and potassium, or another charge balancing cation such as ammonium or a quaternary amine.

One example of the organic sulfur compound of structure (2) is the sodium salt of 3,3′-dithiobis(1-propanesulfonate), which has the following structure (3):

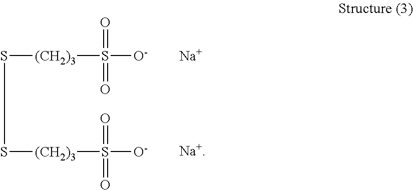

An especially preferred example of the organic sulfur compound of structure (2) is 3,3′-dithiobis(1-propanesulfonic acid), which has the following structure (4):

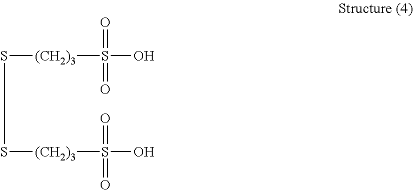

Additional organic sulfur compounds that are applicable are shown by structures (5) through (16):

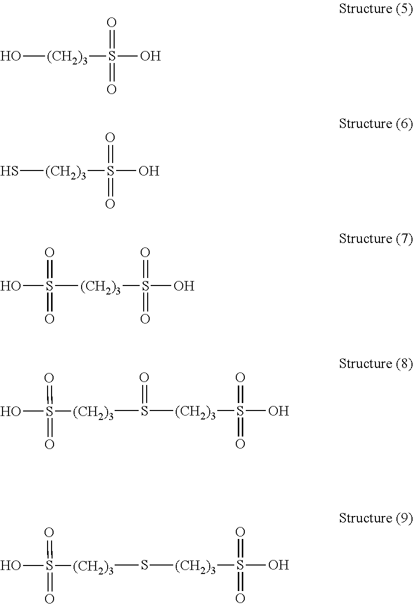

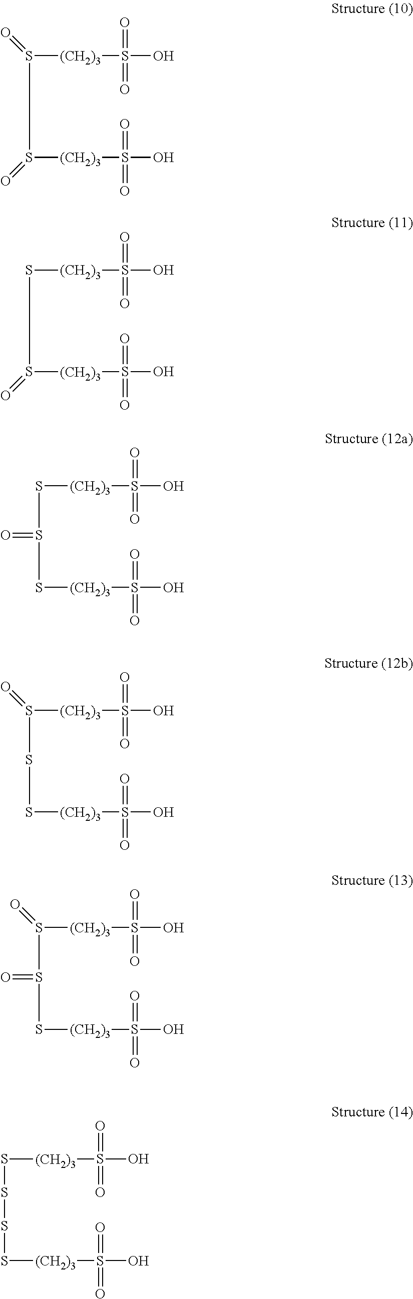

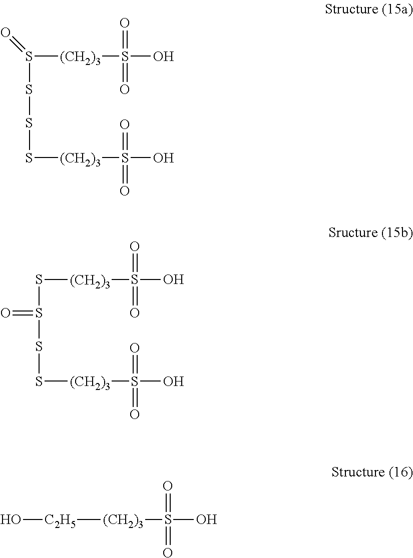

The concentration of the organic sulfur compound may range from about 0.1 ppm to about 100 ppm, such as between about 0.5 ppm to about 20 ppm, preferably between about 1 ppm and about 6 ppm, more preferably between about 1 ppm and about 3 ppm, such as about 1.5 ppm.

As the suppressor component, the electrolytic copper plating bath preferably comprises a polyether of relatively low moderately high molecular weight, e.g., 200 to 50,000, typically 300 to 10,000, more typically 300 to 5,000. The polyether generally comprises alkylene oxide repeat units, most typically ethylene oxide (EO) repeat units, propylene oxide (PO) repeat units, or combinations thereof. In those polymeric chains comprising both EO and PO repeat units, the repeat units may be arranged in random, alternating, or block configurations. The polymeric chains comprising alkylene oxide repeat units may contain residues derived from an initiating reagent used to initiate the polymerization reaction. Compounds applicable for use in the this invention include polypropylene glycol amine (PPGA), in particular poly(propylene glycol)bis(2-aminopropyl ether) (400 g/mol) and low molecular weight polypropylene glycol (PPG). As described, e.g., in U.S. Pat. No. 6,776,893 which is expressly incorporated herein by reference, a polyether suppressor may comprise a block copolymer of polyoxyethylene and polyoxypropylene, a polyoxyethylene or polyoxypropylene derivative of a polyhydric alcohol and a mixed polyoxyethylene and polyoxypropylene derivative of a polyhydric alcohol.

A preferred polyether suppressor compound as described in U.S. Pat. No. 6,776,893 is a polyoxyethylene and polyoxypropylene derivative of glycerine. One such example is propoxylated glycerine having a molecular weight of about 700 g/mol. Another such compound is EO/PO on glycerine having a molecular weight of about 2500 g/mol. Yet another example comprises an EO/PO polyether chain comprising a naphthyl residue, wherein the polyether chain is terminated with a sulfonate moiety. Such a material is available under the trade designation Ralufon NAPE 14-00 from Raschig.

A suppressor may comprise a combination of propylene oxide (PO) repeat units and ethylene oxide (EO) repeat units present in a PO:EO ratio between about 1:9 and about 9:1 and bonded to a nitrogen-containing species, wherein the molecular weight of the suppressor compound is between about 1000 and about 30,000 Alternative suppressors are well known in the art.

The polyether polymer compound concentration may range from about 1 ppm to about 1000 ppm, such as between about 5 ppm to about 200 ppm, preferably between about 10 ppm and about 100 ppm, more preferably between about 10 ppm and about 50 ppm, such as between about 10 ppm and about 20 ppm.

As the leveler, the electrolytic copper plating compositions may further comprise a polymeric material comprising nitrogen containing repeat units. It will be understood that other levelers can be used, but nitrogenous polymeric levelers are preferred.

As a specific example, the leveler may comprise a reaction product of benzyl chloride and hydroxyethyl polyethyleneimine. Such a material may be formed by reacting benzyl chloride with a hydroxyethyl polyethyleneimine that is available under the tradename Lupasol SC 61B from BASF Corporation of Rensselear, N.Y.). The hydroxyethyl polyethyleneimine has a molecular weight generally in the range of 50,000 to about 160,000.

In some embodiments, the additive comprises vinyl-pyridine based compounds. In one embodiment, the compound is a pyridinium compound and, in particular, a quaternized pyridinium salt. A pyridinium compound is a compound derived from pyridine in which the nitrogen atom of the pyridine is protonated. A quaternized pyridinium salt is distinct from pyridine, and quaternized pyridinium salt-based polymers are distinct from pyridine-based polymers, in that the nitrogen atom of the pyridine ring is quaternized in the quaternized pyridinium salt and quaternized pyridinium salt-based polymers. These compounds include derivatives of a vinyl pyridine, such as derivatives of 2-vinyl pyridine, 3-vinyl pyridine, and, in certain preferred embodiments, derivatives of 4-vinyl pyridine. The polymers of the invention encompass homo-polymers of vinyl pyridine, co-polymers of vinyl pyridine, quaternized salts of vinyl pyridine, and quaternized salts of these homo-polymers and co-polymers.

Some specific examples of quaternized poly(4-vinyl pyridine) include, for example, the reaction product of poly(4-vinyl pyridine) with dimethyl sulfate, the reaction product of 4-vinyl pyridine with 2-chloroethanol, the reaction product of 4-vinyl pyridine with benzylchloride, the reaction product of 4-vinyl pyridine with allyl chloride, the reaction product of 4-vinyl pyridine with 4-chloromethylpyridine, the reaction product of 4-vinyl pyridine with 1,3-propane sultone, the reaction product of 4-vinyl pyridine with methyl tosylate, the reaction product of 4-vinyl pyridine with chloroacetone, the reaction product of 4-vinyl pyridine with 2-methoxyethoxymethylchloride, and the reaction product of 4-vinyl pyridine with 2-chloroethylether.

Some examples of quaternized poly(2-vinyl pyridine) include, for example, the reaction product of 2-vinyl pyridine with methyl tosylate, the reaction product of 2-vinyl pyridine with dimethyl sulfate, the reaction product of vinyl pyridine and a water soluble initiator, poly(2-methyl-5-vinyl pyridine), and 1-methyl-4-vinylpyridinium trifluoromethyl sulfonate, among others.

An example of a co-polymer is vinyl pyridine co-polymerized with vinyl imidazole.

The molecular weight of the substituted pyridyl polymer compound additives of the invention in one embodiment is on the order of about 160,000 g/mol or less. While some higher molecular weight compounds are difficult to dissolve into the electroplating bath or to maintain in solution, other higher molecular weight compounds are soluble due to the added solubilizing ability of the quaternary nitrogen cation. The concept of solubility in this context is reference to relative solubility, such as, for example, greater than 60% soluble, or some other minimum solubility that is effective under the circumstances. It is not a reference to absolute solubility. The foregoing preference of 160,000 g/mol or less in certain embodiments is not narrowly critical. In one embodiment, the molecular weight of the substituted pyridyl polymer compound additive is about 150,000 g/mol, or less. Preferably, the molecular weight of the substituted pyridyl polymer compound additive is at least about 500 g/mol. Accordingly, the molecular weight of the substituted pyridyl polymer compound additive may be between about 500 g/mol and about 150,000 g/mol, such as about 700 g/mol, about 1000 g/mol, and about 10,000 g/mol. The substituted pyridyl polymers selected are soluble in the plating bath, retain their functionality under electrolytic conditions, and do not yield deleterious by-products under electrolytic conditions, at least neither immediately nor shortly thereafter.

In those embodiments where the compound is a reaction product of a vinyl pyridine or poly(vinyl pyridine), it is obtained by causing a vinyl pyridine or poly(vinyl pyridine) to react with an alkylating agent selected from among those which yield a product which is soluble, bath compatible, and effective for leveling. In one embodiment candidates are selected from among reaction products obtained by causing vinyl pyridine or poly(vinyl pyridine) to react with a compound of the following structure (17):

R₁-L Structure (17)

wherein R₁ is alkyl, alkenyl, aralkyl, heteroarylalkyl, substituted alkyl, substituted alkenyl, substituted aralkyl, or substituted heteroarylalkyl; and L is a leaving group.

A leaving group is any group that can be displaced from a carbon atom. In general, weak bases are good leaving groups. Exemplary leaving groups are halides, methyl sulfate, tosylates, and the like.

In other embodiments, R₁ is alkyl or substituted alkyl; preferably, R₁ is substituted or unsubstituted methyl, ethyl, straight, branched or cyclic propyl, butyl, pentyl or hexyl; in one embodiment R₁ is methyl, hydroxyethyl, acetylmethyl, chloroethoxyethyl or methoxyethoxymethyl.

In further embodiments, R₁ is alkenyl; preferably, R₁ is vinyl, propenyl, straight or branched butenyl, straight, branched or cyclic pentenyl or straight, branched, or cyclic hexenyl; in one embodiment R₁ is propenyl.

In yet additional embodiments, R₁ is aralkyl or substituted aralkyl; preferably, R₁ is benzyl or substituted benzyl, naphthylalkyl or substituted naphthylalkyl; in one embodiment R1 is benzyl or naphthylmethyl.

In still other embodiments, R₁ is heteroarylalkyl or substituted heteroarylalkyl; preferably, R₁ is pyridylalkyl; particularly, R₁ is pyridylmethyl.

In various embodiments, L is chloride, methyl sulfate (CH₃SO₄⁻), octyl sulfate (C₈H₁₈SO₄⁻), trifluoromethanesulfonate (CF₃SO₃⁻), tosylate (C₇H₇SO₃⁻), or chloroacetate (CH₂ClC(O)O⁻); preferably, L is methyl sulfate, chloride or tosylate.

Water soluble initiators can be used to prepare polymers of vinyl pyridine, though they are not used in the currently preferred embodiments or in the working examples. Exemplary water soluble initiators are peroxides (e.g., hydrogen peroxide, benzoyl peroxide, peroxybenzoic acid, etc.) and the like, and water soluble azo initiators such as 4,4′-Azobis(4-cyanovaleric acid).

In a variety of embodiments, the leveler component comprises a mixture of one of the above-described polymers with a quantity of a monomer which is, for example, a monomeric vinyl pyridine derivative compound. In one such embodiment, the mixture is obtained by quaternizing a monomer to yield a quaternized salt which then undergoes spontaneous polymerization. The quaternized salt does not completely polymerize; rather, it yields a mixture of the monomer and spontaneously generated polymer.

The compound may be prepared by quaternizing 4-vinyl pyridine by reaction with dimethyl sulfate. Polymerization occurs according to the following reaction scheme (45-65° C.):

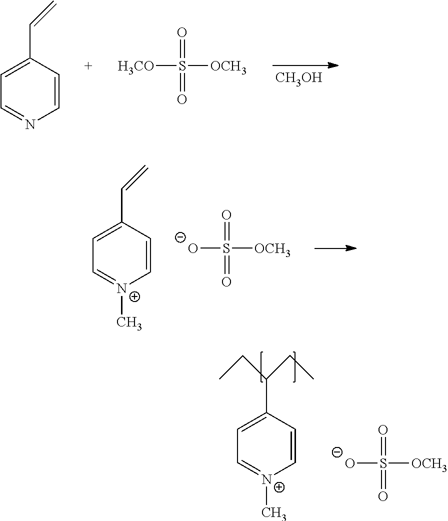

The average molecular weight of the polymer is generally less than 10,000 g/mol. The monomer fraction may be increased with an increase in amount of methanol used in the quaternization reaction; that is, the degree of spontaneous polymerization is decreased.

In some embodiments, the composition may comprise compounds comprising quaternized dipyridyls. In general, quaternized dipyridyls are derived from the reaction between a dipyridyl compound and an alkylating reagent. Although such a reaction scheme is a common method of quaternizing dipyridyls, the compounds are not limited to only those reaction products that are derived from the reaction between a dipyridyl compound and an alkylating reagent, but rather to any compound having the functionality described herein below.

Dipyridyls that may be quaternized to prepare the levelers of the present invention have the general structure (18):

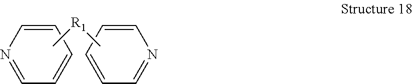

wherein R₁ is a moiety that connects the pyridine rings. In Structure (18), each line from R₁ to one of the pyridine rings denotes a bond between an atom in the R₁ moiety and one of the five carbon atoms of the pyridine ring. In some embodiments, R₁ denotes a single bond wherein one carbon atom from one of the pyridine rings is directly bonded to one carbon atom from the other pyridine ring.

In some embodiments, the R₁ connection moiety may be an alkyl chain, and the dipyridyl may have the general structure (19):

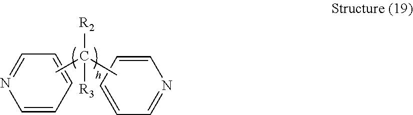

wherein h is an integer from 0 to 6, and R₂ and R₃ are each independently selected from among hydrogen or a short alkyl chain having from 1 to about 3 carbon atoms. In Structure (19), each line from a carbon in the alkyl chain to one of the pyridine rings denotes a bond between a carbon atom in the alkyl chain and one of the five carbon atoms of the pyridine ring. In embodiments wherein h is 0, the connecting moiety is a single bond, and one carbon atom from one of the pyridine rings is directly bonded to one carbon atom from the other pyridine ring. In certain preferred embodiments, h is 2 or 3. In certain preferred embodiments, h is 2 or 3, and each R₂ and R₃ is hydrogen.

In some embodiments, the R₁ connecting moiety may contain a carbonyl, and the dipyridyl may have the general structure (20):

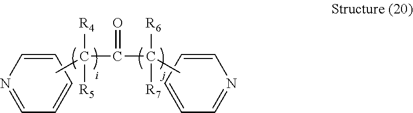

wherein i and j are integers from 0 to 6, and R₄, R₅, R₆, and R₆ are each independently selected from among hydrogen or a short alkyl chain having from 1 to about 3 carbon atoms. In Structure (20), each line from a carbon in the connecting moiety to one of the pyridine rings denotes a bond between the carbon atom in the connecting moiety and one of the five carbon atoms of the pyridine ring. In embodiments wherein i and j are both 0, the carbon atom of the carbonyl is directly bonded to one carbon atom in each of the pyridine rings.

Two compounds in the general class of dipyridyls of structure (20), in which i and j are both 0, are 2,2′-dipyridyl ketone (structure (21)) and 4,4′-dipyridyl ketone (structure (22)), having the structures shown below:

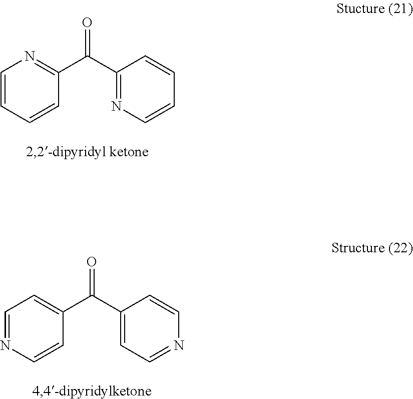 [SMILES: O=C(c1ccccn1)c1ccccn1 ; O=C(c1ccncc1)c1ccncc1]

In some embodiments, the R₁ connecting moiety may contain an amine, and the dipyridyl may have the general structure (23):

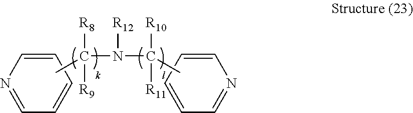

wherein k and 1 are integers from 0 to 6, and R₈, R₉, R₁₀, R₁₁, and R₁₂ are each independently selected from among hydrogen or a short alkyl chain having from 1 to about 3 carbon atoms. In Structure (23), each line from a carbon in the connecting moiety to one of the pyridine rings denotes a bond between the carbon atom in the connecting moiety and one of the five carbon atoms of the pyridine ring. In embodiments wherein k and 1 are both 0, the nitrogen is directly bonded to one carbon atom in each of the pyridine rings.

One compound in the general class of dipyridyls of structure (23), in which k and 1 are both 0 and R₁₂ is hydrogen, is dipyridin-4-ylamine having the structure (24) shown below:

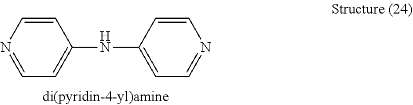 [SMILES: c1cc(Nc2ccncc2)ccn1]

In some embodiments, the R₁ connecting moiety comprises another pyridine. Such a structure is actually a terpyridine having the general structure (25):

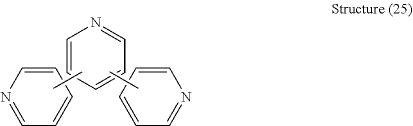

In this structure, each line from each pyridine ring denotes a bond between one carbon on one ring and another carbon on another ring.

One such compound in the general class compounds of structure (25) is a terpyridine having the structure (26):

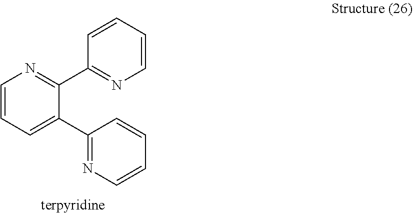 [SMILES: c1ccc(-c2cccnc2-c2ccccn2)nc1]

Preferably, the dipyridyl is chosen from the general class of dipyridyls of general structure (19), and further in which R₂ and R₃ are each hydrogen. These dipyridyls have the general structure (27):

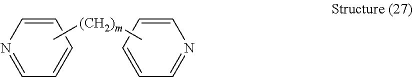

wherein in is an integer from 0 to 6. In Structure (27), each line from a carbon atom in the alkyl chain to one of the pyridine rings denotes a bond between a carbon atom in the alkyl chain and one of the five carbon atoms of the pyridine ring. In embodiments wherein m is 0, the connecting moiety is a single bond, and one carbon atom from one of the pyridine rings is directly bonded to one carbon atom from the other pyridine ring. In certain preferred embodiments, m is 2 or 3.

Dipyridyls of the above general structure (27) include 2,2′-dipyridyl compounds, 3,3′-dipyridyl compounds, and 4,4′-dipyridyl compounds, as shown in the following structures (28), (29), and (30), respectively:

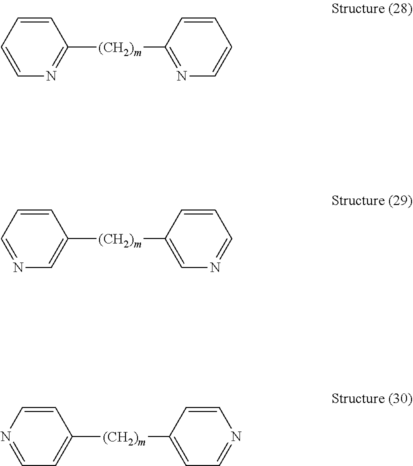

wherein m is an integer from 0 to 6. When m is 0, the two pyridine rings are directly bonded to each other through a single bond. In preferred embodiments, m is 2 or 3.

2,2′-dipyridyl compounds include 2,2′-dipyridyl, 2,2′-ethylenedipyridine (1,2-Bis(2-pyridyl)ethane), Bis(2-pyridyl)methane, 1,3-Bis(2-pyridyl)propane, 1,4-Bis(2-pyridyl)butane, 1,5-Bis(2-pyridyl)pentane, and 1,6-Bis(2-pyridyl)hexane.

3,3′-dipyridyl compounds include 3,3′-dipyridyl, 3,3′-ethylenedipyridine (1,2-Bis(3-pyridyl)ethane), Bis(3-pyridyl)methane, 1,3-Bis(3-pyridyl)propane, 1,4-Bis(3-pyridyebutane, 1,5-Bis(3-pyridyl)pentane, and 1,6-Bis(3-pyridyl)hexane.

4,4′-dipyridyl compounds include, for example, 4,4′-dipyridyl, 4,4′-ethylenedipyridine (1,2-Bis(4-pyridyl)ethane), Bis(4-pyridyl)methane, 1,3-Bis(4-pyridyl)propane, 1,4-Bis(4-pyridyl)butane, 1,5-Bis(4-pyridyl)pentane, and 1,6-Bis(4-pyridyl)hexane.

Of these dipyridyl compounds, 4,4′-dipyridyl compounds are preferred since compounds based on 4,4′-dipyridyl have been found to be particularly advantageous levelers in terms of achieving low impurity inclusion and underplate and overplate reduction. In particular, 4,4′-dipyridyl, having the structure (31), 4,4′-ethylenedipyridine, having structure (32), and 1,3-Bis(4-pyridyl)propane having structure (33) are more preferred. Compounds based on the dipyridyls of structure (32) and (33) are currently the most preferred levelers.

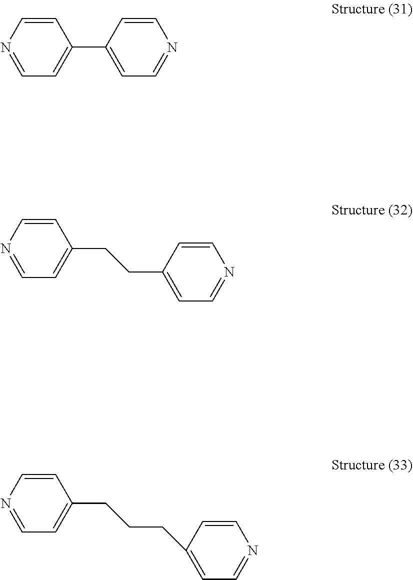 [SMILES: c1cc(-c2ccncc2)ccn1 ; c1cc(CCc2ccncc2)ccn1 ; c1cc(CCCc2ccncc2)ccn1]

These compounds are quaternized dipyridyl compounds, typically prepared by alkylating at least one and preferably both of the nitrogen atoms. Alkylation occurs by reacting the above-described dipyridyl compounds with an alkylating agent. In some embodiments, the alkylating agent may be of a type particularly suitable for forming polymers. In some embodiments, the alkylating agent is of a type that reacts with the dipyridyl compound but does not form polymers.

Alkylating agents that are suitable for reacting with dipyridyl compounds that generally form non-polymeric levelers may have the general structure (34):

Y—(CH₂)ₒ-A Structure (34)

wherein

A may be selected from among hydrogen, hydroxyl (—OH), alkoxy (—OR₁), amine (—NR₂R₃R₄), glycol

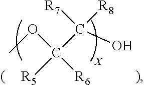

aryl

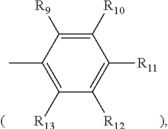

and sulfhydryl or thioether (—SR₁₄);

o is an integer between one and six, preferably one or two; and

X is an integer from one to about four, preferably one or two; and

Y is a leaving group. The leaving group may be selected from among, for example, chloride, bromide, iodide, tosyl, triflate, sulfonate, mesylate, dimethyl sulfonate, fluorosulfonate, methyl tosylate, brosylate, or nosylate.

In each A group above, the single line emanating from the functional moiety denotes a bond between an atom in the A moiety, e.g., oxygen, nitrogen, or carbon, and a carbon of the —(CH₂)ₒ— akylene group. Additionally, the R₁ through R₁₄ groups denoted in the A moieties of Structure (34) are independently hydrogen; substituted or unsubstituted alkyl having from one to six carbon atoms, preferably one to three carbon atoms; substituted or unsubstituted alkylene having from one to six carbon atoms, preferably from one to three carbon atoms; or substituted or unsubstituted aryl. The alkyl may be substituted with one or more of the following substituents: halogen, heterocyclo, alkoxy, alkenoxy, alkynoxy, aryloxy, hydroxy, protected hydroxy, hydroxycarbonyl, keto, acyl, acyloxy, nitro, amino, amido, nitro, phosphono, cyano, thiol, ketals, acetals, esters and ethers. In general, the various alkyl R groups are hydrogen or unsubstituted alkyl.

With regard to the aryl group, any of the R₆ through R₁₀ carbons, together with an adjacent R group and the carbons to which they are bonded may form an aryl group, i.e., the aryl group comprises a fused ring structure, such as a naphthyl group.

Exemplary A groups include:

hydrogen,

hydroxyl (—OH),

methoxy (—OCH₃),

ethoxy (—OCH₂CH₃),

propoxy (—OCH₂CH₂CH₃ or

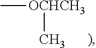

amino (—NH₂),

methylamino (—NHCH₃),

dimethylamino

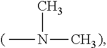

ethylene glycol (—O—CH₂CH₂—OH),

diethylene glycol

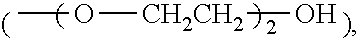

propylene glycol (—OCH₂CH₂CH₂—OH or

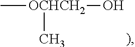

dipropylene glycol

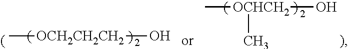

phenyl

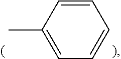

naphthenyl and

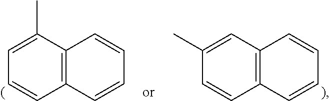

sulfhydryl (—SH), or derivatives of each of these.

Preferably, A is selected from among:

hydrogen,

hydroxyl (—OH),

methoxy (—OCH₃),

ethoxy (—OCH₂CH₃),

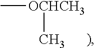

propoxy (—OCH₂CH₂CH₃ or

ethylene glycol (—OCH₂CH₂—OH),

diethylene glycol

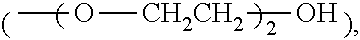

propylene glycol (—OCH₂CH₂CH₂OH or

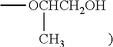

phenyl

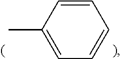

and

naphthenyl

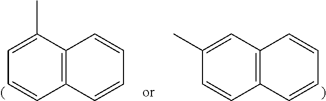

or derivatives of each of these.

More preferably, A is selected from among:

hydroxyl (—OH),

ethylene glycol (—O—CH₂CH₂—OH),

propylene glycol (—OCH₂CH₂CH₂OH or

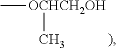

and

phenyl

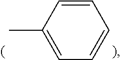

or derivatives of each of these.

Preferably, in the alkylating agents of Structure (34), o is one or two, and Y is chloride.

Alkylating agents that react with the dipyridyl compounds and generally form polymeric compounds may have the general structure (35):

Y—(CH₂)ₚ—B—(CH₂)_{q}—Z Structure (35)

wherein

B may be selected from among:

a single bond, an oxygen atom (—O—), a methenyl hydroxide

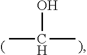

a carbonyl

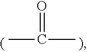

an amino

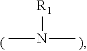

an imino

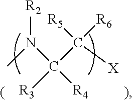

a sulfur atom (—S—), a sulfoxide

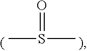

a phenylene

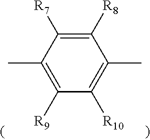

and a glycol

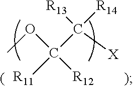

and

p and q may be the same or different, are integers between 0 and 6, preferably from 0 to 2, wherein at least one of p and q is at least 1;

X is an integer from one to about four, preferably one or two; and

Y and Z are leaving groups. The leaving group may be selected from among, for example, chloride, bromide, iodide, tosyl, triflate, sulfonate, mesylate, methosulfate, fluorosulfonate, methyl tosylate, brosylate, or nosylate.

In each B group above, the single line emanating from the functional moiety denotes a bond between an atom in the B moiety, e.g., oxygen, nitrogen, or carbon, and a carbon of the —(CH₂)ₚ— and —CH₂)_{q}— akylene groups. Additionally, the R₁ through R₁₄ groups in denoted in the B moieties of Structure (35) are independently hydrogen; substituted or unsubstituted alkyl having from one to six carbon atoms, preferably one to three carbon atoms; substituted or unsubstituted alkylene having from one to six carbon atoms, preferably from one to three carbon atoms; or substituted or unsubstituted aryl. The alkyl may be substituted with one or more of the following substituents: halogen, heterocyclo, alkoxy, alkenoxy, alkynoxy, aryloxy, hydroxy, protected hydroxy, hydroxycarbonyl, keto, acyl, acyloxy, nitro, amino, amido, nitro, phosphono, cyano, thiol, ketals, acetals, esters and ethers. In general, the various R groups are hydrogen or unsubstituted alkyl, and even more preferably, the R groups are hydrogen.

Preferably, B is selected from among:

an oxygen atom (—O—),

a methenyl hydroxide

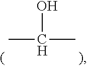

a carbonyl

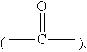

a phenylene group

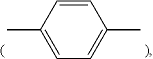

an ethylene glycol group

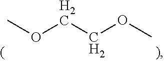

a propylene glycol group

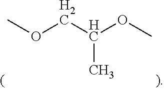

More preferably, B is selected from among:

an oxygen atom (—O—),

a methenyl hydroxide

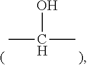

a carbonyl

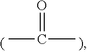

a phenylene group and

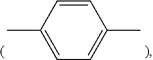

an ethylene glycol group

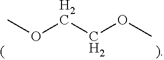

Preferably, in the alkylating agents of Structure (35), p and q are both one or are both two, and Y and Z are both chloride.

Another class of alkylating agents that may form a polymeric leveler when reacted with the dipyridyl compounds includes an oxirane ring and has the general structure (36):

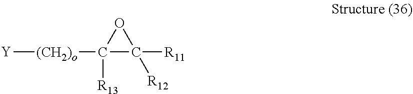

wherein

R₁₁, R₁₂, and R₁₃ are hydrogen or substituted or unsubstituted alkyl having from one to six carbon atoms, preferably from one to three carbon atoms;

o is an integer between one and six, preferably one or two; and

Y is a leaving group. The leaving group may be selected from among, for example, chloride, bromide, iodide, tosyl, triflate, sulfonate, mesylate, methosulfate, fluorosulfonate, methyl tosylate, brosylate, or nosylate.

Preferably, R₁₁, R₁₂, and R₁₃ are hydrogen and the alkylating agent has the following general structure (37):

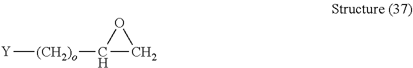

wherein o and Y are as defined in connection with Structure (36).

Preferably, o is one, Y is chloride, and the alkylating agent of general Structure (36) is epichlorohydrin.

The reaction product causes the leaving group to form an anion in the reaction mixture. Since chloride is commonly added to electrolytic copper plating compositions, Y and Z are preferably chloride. While the other leaving groups may be used to form the leveling compounds of the present invention, these are less preferred since they may adversely affect the electrolytic plating composition. Leveling agents that are charge balanced with, for example, bromide or iodide, are preferably ion exchanged with chloride prior to adding the leveling compound to the electrolytic copper plating compositions of the present invention.

Specific alkylating agents of the above structure (34) include, for example, 2-chloroethylether, benzyl chloride, 2-(2-chloroethoxy)ethanol, chloroethanol, 1-(chloromethyl)-4-vinylbenzene, and 1-(chloromethyl)naphthalene.

Specific alkylating agents of the above structure (35) include, for example, 1-chloro-2-(2-chloroethoxy)ethane, 1,2-bis(2-chloroethoxy)ethane, 1,3-dichloropropan-2-one, 1,3-dichloropropan-2-ol, 1,2-dichloroethane, 1,3-dichloropropane, 1,4-dichlorobutane, 1,5-dichloropentane, 1,6-dichlorohexane, 1,7-dichloroheptane, 1,8-dichlorooctane, 1,2-di(2-chloroethyl)ether, 1,4-bis(chloromethyl)benzene, m-di(chloromethyl)benzene, and o-di(chloromethyl)benzene.

A specific alkylating agent of the above structure (36) is epichlorohydrin. The alkylating agents may comprise bromide, iodide, tosyl, triflate, sulfonate, mesylate, dimethyl sulfonate, fluorosulfonate, methyl tosylate, brosylate, or nosylate derivatives of the above chlorinated alkylating agents, but these are less preferred since chloride ion is typically added to electrolytic copper plating compositions, and the other anions may interfere with copper deposition.

A wide variety of leveler compounds may be prepared from the reaction of the dipyridyl compounds having the structures (18) through (33) and the alkylating agents having the general structures (34) through (37). Reactions to prepare the leveler compounds may occur according to the conditions described in Nagase et al., U.S. Pat. No. 5,616,317, the entire disclosure of which is hereby incorporated as if set forth in its entirety. In the reaction, the leaving groups are displaced when the nitrogen atoms on the pyridyl rings react with and bond to the methylene groups in the dihalogen compound. Preferably, the reaction occurs in a compatible organic solvent, preferably having a high boiling point, such as ethylene glycol or propylene glycol.

In some embodiments, the leveler compounds of the present invention are polymers, and the levelers may be prepared by selecting reaction conditions, i.e., temperature, concentration, and the alkylating agent such that the dipyridyl compound and alkylating agent polymerize, wherein the repeat units of the polymer comprise one moiety derived from the dipyridyl compound and one moiety derived from the alkylating. In some embodiments, the dipyridyl compound has the structure (27) and the alkylating agent has the general structure depicted above in Structure (35). In some embodiments, therefore, the leveler compound is a polymer comprising the following general structure (38):

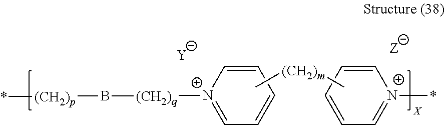

wherein B, m, p, q, Y, and Z are as defined with regard to structures (27) and (35), and X is an integer that is at least 2. Preferably, X ranges from 2 to about 100, such as from about 2 to about 50, from about 2 to about 25, and even more preferably from about 4 to about 20.

As stated above, preferred dipyridyl compounds are based on 4,4′-dipyridyl compounds. In some preferred embodiments, the leveler compound is a reaction product of 4,4′-dipyridyl of structure (31) and an alkylating agent of structure (35). Reaction conditions, i.e., temperatures, relative concentrations, and choice of alkylating agent may be selected such that 4,4′-dipyridyl and the alkylating agent polymerize, wherein the repeat units of the polymer comprise one moiety derived from 4,4′-dipyridyl and one moiety derived from the alkylating agent. In some embodiments, therefore, the leveler compound is a polymer comprising the following general structure (39):

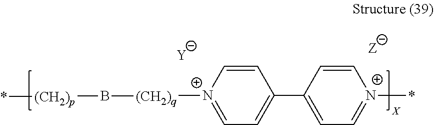

wherein B, p, q, Y, and Z are as defined with regard to structure (35), and X is an integer of at least 2, preferably from 2 to 100, such as from 2 to 50, and more preferred from 3 to about 20.

One particular leveler compound in the class of levelers of structure (39) is the reaction product of the 4,4′-dipyridyl and an alkylating agent wherein B is the oxygen atom, p and q are both 2, and Y and Z are both chloride, i.e., 1-chloro-2-(2-chloroethoxy)ethane. This leveler compound is a polymer comprising the following structure (40):

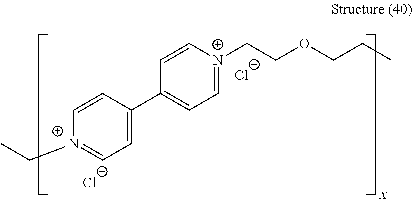

wherein X is an integer of at least 2, preferably from 2 to 100, such as from 2 to 50, and more preferred from 3 to about 20.

In some preferred embodiments, the leveler compound is a reaction product of 4,4′-dipyridyl of structure (32) and an alkylating agent of structure (35). Reaction conditions, i.e., temperatures, relative concentrations, and choice of alkylating agent may be selected such that 4,4′-ethylenedipyridine and the alkylating agent polymerize, wherein the repeat units of the polymer comprise one moiety derived from 4,4′-ethylenedipyridine and one moiety derived from the alkylating agent. In some embodiments, therefore, the leveler compound is a polymer comprising the following general structure (41):

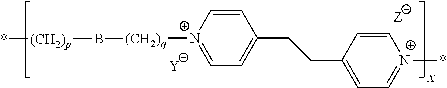

wherein B, p, q, Y, and Z are as defined with regard to structure (35) and X is an integer of at least 2, preferably from 2 to 100, such as from 2 to 50, and more preferred from 3 to about 20.

One particular leveler compound in the class of levelers of structure (41) is polymer that may be prepared from reacting 4,4′-ethylenedipyridine and an alkylating agent wherein B is the oxygen atom, p and q are both 2, and Y and Z are both chloride, i.e., 1-chloro-2-(2-chloroethoxy)ethane. This leveler compound is a polymer comprising the following structure (42):

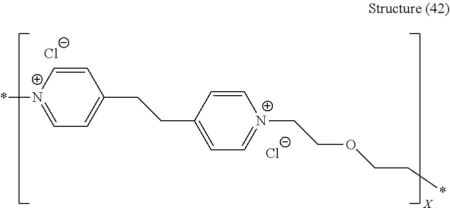

wherein X is an integer of at least 2, preferably from 2 to 100, such as from 2 to 50, and more preferred from 3 to about 20. In one preferred leveler of structure (42), X is an average value from about 3 to about 12, such as between about 4 and about 8, or even about 5 to about 6. In one preferred leveler of structure (42), X is an average value from about 10 to about 24, such as between about 12 to about 18, or even about 13 to about 14.

Another leveler compound in the class of levelers of structure (41) is a polymer that may be prepared by reacting 4,4′-ethylenedipyridine and an alkylating agent wherein B is the ethylene glycol, p and q are both 2, and Y and Z are both chloride, i.e., 1,2-bis(2-chloroethoxy)ethane. This leveler compound is a polymer comprising the following structure (43):

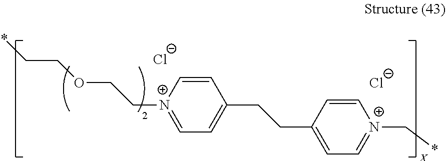

wherein X is an integer of at least 2, preferably from 2 to 100, such as from 2 to 50, and more preferred from 3 to about 20.

Another leveler compound in the class of levelers of structure (41) is a polymer that may be prepared by reacting 4,4′-ethylenedipyridine and an alkylating agent wherein B is the carbonyl, p and q are both 1, and Y and Z are both chloride, i.e., 1,3-dichloropropan-2-one. This leveler compound is a polymer comprising the following structure (44):

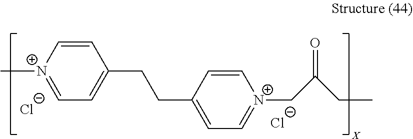

wherein X is an integer of at least 2, preferably from 2 to 100, such as from 2 to 50, and more preferred from 3 to about 20.

Another leveler compound in the class of levelers of structure (41) is a polymer that may be prepared by reacting 4,4′-ethylenedipyridine and an alkylating agent wherein B is the methenyl hydroxide, p and q are both 1, and Y and Z are both chloride, i.e., 1,3-dichloropropan-2-ol. This leveler compound is a polymer comprising the following structure (45):

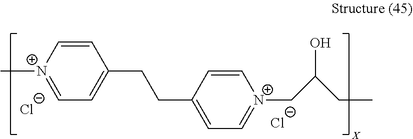

wherein X is an integer of at least 2, preferably from 2 to 100, such as from 2 to 50, and more preferred from 3 to about 20.

Another leveler compound in the class of levelers of structure (41) is a polymer that may be prepared by reacting 4,4′-ethylenedipyridine and an alkylating agent wherein B is the phenylene, p and q are both 1, and Y and Z are both chloride, i.e., 1,4-bis(chloromethyl)benzene. This leveler compound is a polymer comprising the following structure (46):

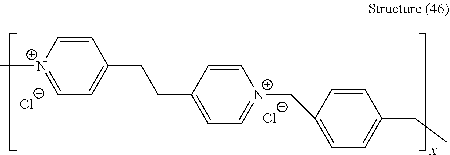

wherein X is an integer of at least 2, preferably from 2 to 100, such as from 2 to 50, and more preferred from 3 to about 20.

In some preferred embodiments, the leveler compound is a reaction product of 4,4′-dipyridyl of structure (33) and an alkylating agent of structure (35). Reaction conditions, i.e., temperatures, relative concentrations, and choice of alkylating agent may be selected such that 1,3-di(pyridin-4-yl)propane and the alkylating agent polymerize, wherein the repeat units of the polymer comprise one moiety derived from 1,3-di(pyridin-4-yl)propane and one moiety derived from the alkylating agent. In some embodiments, therefore, the leveler compound is a polymer comprising the following general structure (47):

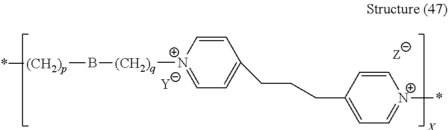

wherein B, p, q, Y, and Z are as defined with regard to structure (35) and X is an integer of at least 2, preferably from 2 to 100, such as from 2 to 50, and more preferred from 3 to about 20.

One particular leveler compound in the class of levelers of structure (47) is polymer that may be prepared from reacting 1,3-di(pyridin-4-yl)propane and an alkylating agent wherein B is the oxygen atom, p and q are both 2, and Y and Z are both chloride, i.e., 1-chloro-2-(2-chloroethoxy)ethane. This leveler compound is a polymer comprising the following structure (48):

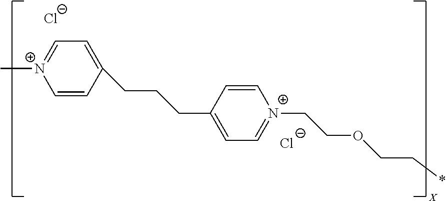

wherein X is an integer of at least 2, preferably from 2 to 100, such as from 2 to 50, and more preferred from 3 to about 20, such as from about 4 to about 8, or from about 12 to about 16. In one preferred leveler of structure (48), X is an average value from about 5 to about 6. In one preferred leveler of structure (48), X is an average value from about 13 to about 14.

In some embodiments, the leveler compounds may be prepared by reacting a dipyridyl compound having the structure (27) and an alkylating agent having the general structure depicted above in Structure (35) in a manner that does not form a polymeric leveler. That is, the levelers may be prepared by selecting reaction conditions, i.e., temperature, concentration, in which the alkylating agent such that the dipyridyl compound and alkylating agent react but do not polymerize. The leveler compound may comprise the following structure (49):

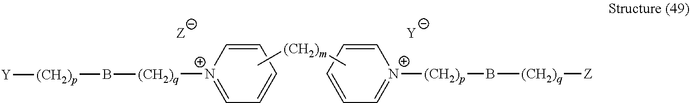

wherein B, m, p, q, Y, and Z are as defined with regard to structures (27) and (35).

As stated above, preferred dipyridyl compounds have general structure (27) such that preferred levelers are based on 4,4′-dipyridyl compounds. In some preferred embodiments, the leveler compound is a reaction product of 4,4′-dipyridyl of structure (31) and an alkylating agent of structure (35) and may comprise the following structure (50):

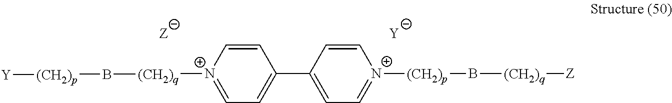

wherein B, p, q, Y, and Z are as defined with regard to Structure (35).

One particular leveler compound in the class of levelers of structure (50) is the reaction product of the 4,4′-dipyridyl and an alkylating agent wherein B is the oxygen atom, p and q are both 2, and Y and Z are both chloride, i.e., 1-chloro-2-(2-chloroethoxy)ethane. This leveler compound may comprise the following structure (51):

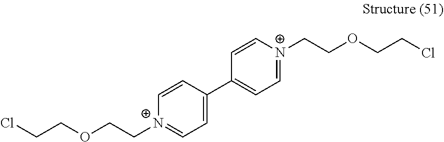 [SMILES: ClCCOCC[n+]1ccc(-c2cc[n+](CCOCCCl)cc2)cc1]

In some preferred embodiments, the leveler compound is a reaction product of 4,4′-dipyridyl of structure (32) and an alkylating agent of structure (35). In some embodiments, therefore, the leveler compound may comprise the following structure (52):

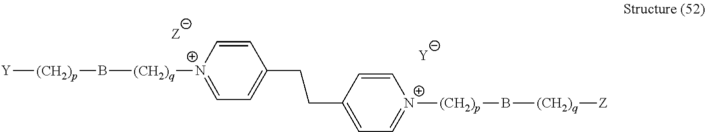

wherein B, p, q, Y, and Z are as defined with regard to structure (35).

One particular leveler compound in the class of levelers of structure (52) is the reaction product of the 4,4′-ethylenedipyridine and an alkylating agent wherein B is the oxygen atom, p and q are both 2, and Y and Z are both chloride, i.e., 1-chloro-2-(2-chloroethoxy)ethane. This leveler compound may comprise the following structure (53):

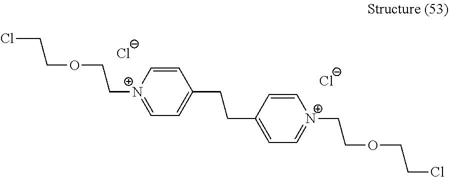 [SMILES: ClCCOCC[n+]1ccc(CCc2cc[n+](CCOCCCl)cc2)cc1 ; [Cl-] ; [Cl-]]

Another leveler compound in the class of levelers of structure (52) is a polymer that may be prepared by reacting 4,4′-ethylenedipyridine and an alkylating agent wherein B is the ethylene glycol, p and q are both 2, and Y and Z are both chloride, i.e., 1,2-bis(2-chloroethoxy)ethane. This leveler compound may comprise the following structure (54):

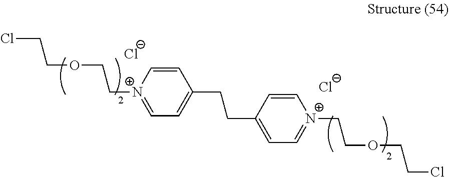

In some embodiments, the leveler compound may be prepared by reacting a dipyridyl molecule having the structure (27) and an alkylating agent having the general structure depicted above in structure (34). This leveler compound may comprise the following structure (55):

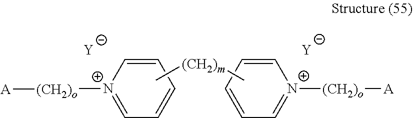

wherein A, m, o, and Y are as defined with regard to structures (27) and (34).

In some preferred embodiments, the leveler compound is a reaction product of 4,4′-dipyridyl of structure (32) and an alkylating agent of structure (34). In some embodiments, therefore, the leveler compound may comprise the following structure (56):

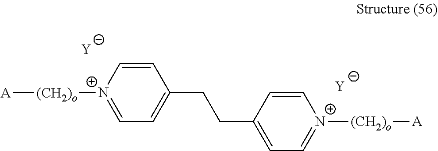

wherein A, o, and Y are as defined with regard to structure (34).

One particular leveler compound in the class of levelers of structure (56) is the reaction product of the 4,4′-ethylenedipyridine and an alkylating agent wherein A is the phenyl group, o is 1, and Y is chloride, i.e., benzyl chloride. This leveler compound may comprise the following structure (57):

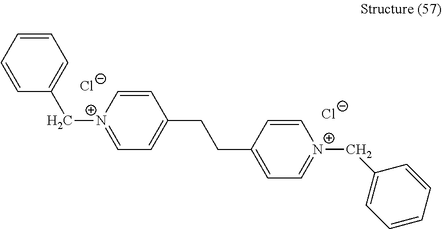 [SMILES: c1ccc(C[n+]2ccc(CCc3cc[n+](Cc4ccccc4)cc3)cc2)cc1 ; [Cl-] ; [Cl-]]

The leveler concentration may range from about 1 ppm to about 100 ppm, such as between about 2 ppm to about 50 ppm, preferably between about 2 ppm and about 20 ppm, more preferably between about 2 ppm and about 10 ppm, such as between about 5 ppm and about 10 ppm.

wetting of the vias with the Cu filling chemistry. An exemplary solution useful for degassing the wafer surface if MICROFAB® PW 1000, available from Enthone Inc. (West Haven, Conn.). After degassing, TSV features located in the wafer is copper metallized using the electrolytic copper deposition composition of the present invention.

The exact configuration of the plating equipment is not critical to the invention. If line power is used for the electrolysis, the electrolytic circuit includes a rectifier for converting the alternating current to direct current and a potentiostat by which the polarity of the electrodes may be reversed and the applied potential controlled to achieve the current pattern utilized in the process of the invention. A membrane separator may be used to divide the chamber containing the electrolytic solution into an anode chamber in which a portion of the electrolytic solution comprising an anolyte is in contact with the anode and a cathode chamber in which a portion of the electrolytic solution comprising a catholyte is in contact with the metalizing surface, which functions as the cathode during the forward current plating process. The cathode and anode may be horizontally or vertically disposed in the tank.

During operation of the electrolytic plating system, copper metal is plated on the surface of a cathode substrate when the power source is energized and power directed through the rectifier to the electrolytic circuit. The bath temperature is typically between about 15° and about 60° C., preferably between about 35° and about 45° C. It is preferred to use an anode to cathode ratio of about 1:1, but this may also vary widely from about 1:4 to 4:1. The process also uses mixing in the electrolytic plating tank which may be supplied by agitation or preferably by the circulating flow of recycle electrolytic solution through the tank.

1. (canceled)

2. (canceled)

3. A process for forming an array of copper features on a semiconductor substrate in wafer level packaging for interconnecting an electronic circuit of a semiconductor device with a circuit external to the device, the process comprising:
supplying current to an aqueous electrodeposition composition in contact with a cathode comprising an array of under bump structures on a semiconductor assembly, said aqueous electrodeposition composition comprising a source of copper ions, an acid, an accelerator, a suppressor, and a leveler;
wherein an array of copper pillars is electrodeposited on the array of under bump structures comprising a seminal conductive layer for initiating the electrodeposition of copper from the aqueous electrodeposition composition; and
wherein the current takes a form selected from the group consisting of square wave and square wave with open circuit;
wherein each of the electrodeposited copper pillars within the array of electrodeposited copper pillars has a height of from about 190 to 230 micrometers;
wherein each of the electrodeposited copper pillars within the array of electrodeposited copper pillars has a within feature (WIF) percentage of 10 percent or less; and
wherein the rate of growth of the electrodeposited copper pillars within the array of electrodeposited copper pillars in a vertical direction from the seminal conductive layer is at least about 2.5 μm/min.

4. (canceled)

5. A process as set forth in claim 3, wherein each of the under bump structures is within a concavity comprising sidewalls.

6. A process as set forth in claim 5, wherein lateral growth of the electrodeposited copper pillars during electrodeposition is constrained by the sidewall(s) of the concavity.

7. (canceled)

8. A process as set forth in claim 3, wherein growth of a distal end of the electrodeposited copper pillars is not laterally constrained during electrodeposition.

9. (canceled)

10. A process as set forth in claim 3, wherein the seminal conductive layer comprises a copper seed layer.

11. (canceled)

12. A process as set forth in claim 3, wherein the diameter of the copper bump or pillars is between about 1 and about 30 μm.

13. (canceled)

14. (canceled)

15. (canceled)

16. (canceled)

17. (canceled)

18. A process as set forth in claim 3, wherein each of the copper pillars produced by the process has an aspect ratio of at least about 1:1.

19. A process as set forth in claim 3, wherein each of the copper pillars produced by the process has an aspect ratio between about 1:1 and about 6:1.

20. (canceled)

21. A process as set forth in claim 3, wherein each of the copper pillars of said array of copper pillars is substantially equally spaced from immediately neighboring pillars of the array.

22. (canceled)

23. A process as set forth in claim 3, wherein the array of electrodeposited copper pillars has a within feature (WID) uniformity of 10 percent or less.

24. A process as set forth in claim 3, wherein the source of copper ions is copper sulfate.
